(19) United States
(12) Patent Application Publication
(10) Pub. No.: US 2012/0048331 A1
(43) Pub. Date: Mar. 1, 2012

(54) PHOTOVOLTAIC MODULE AND JUNCTION BOX THEREOF

(75) Inventors: Chen-Yu Yang, Keelung City (TW); Hao-Kun Lien, Taipei County (TW)

(73) Assignee: Du Pont Apollo Limited, Hong Kong (HK)

(21) Appl. No.: 13/190,491

(22) Filed: Jul. 26, 2011

(30) Foreign Application Priority Data
Aug. 30, 2010 (CN) 201010270435.X

(51) Int. Cl. H01L 31/05; H05K 5/00

(52) U.S. Cl. 136/244; 174/520

(57) ABSTRACT

A photovoltaic module and a junction box thereof are provided. The photovoltaic module includes a photovoltaic panel, a box body, an electrode and a metal fastener. The photovoltaic panel has a plurality of interconnecting wires. The electrode is located in the box body for electrically connecting to an interconnecting wire of a photovoltaic panel. The metal fastener is fixed on the electrode for clamping an interconnecting wire between the metal fastener and the electrode.

### RELATED APPLICATIONS

This application claims priority to China Application Serial Number 201010270435.X, filed Aug. 30, 2010, which is herein incorporated by reference.

### BACKGROUND

1. Field of Invention

The present invention relates to a photovoltaic module. More particularly, the present invention relates to a junction box of a photovoltaic module.

2. Description of Related Art

As a new eco-friendly energy resource, solar energy gradually attracts people's attention and is widely used in daily life. Generally speaking, the solar energy can be converted into electrical energy or thermal energy for use. Currently, a solar module is mostly built on the roof of a building or a single-storey house, and has two positive and negative wires connected to a load. In sunshine, the solar module outputs a certain working voltage and working current for the operation of the load. In a cloudy day or in an evening, the electrical energy stored in a battery during daytime is needed to operate the load.

The two positive and negative wires of the solar module are led out from the junction box, and the junction box functions to connect the inner and outer wires and provide an environment insulated from the ambient. FIG. 1 is a cross-sectional view of a conventional photovoltaic module 100. When a junction box 104 is mounted on the back side of a photovoltaic panel 102, interconnecting wires 106a and 106b of the photovoltaic panel 102 pass through an opening of the junction box 104 and are electrically connected to two electrodes 108a and 108b. Currently, the interconnecting wires 106a and 106b are connected to the two electrodes (108a and 108b) mostly by welding. Whether the welding is firm depends on the welding skill of the operator. Usually, each of the interconnecting wires (106a and 106b) is firstly bent into an L-shape for facilitating subsequent welding process. However, if the welding spots are not firm enough, an interconnecting wire may falls off from an electrode (for example, the interconnecting wire 106b falls off from the electrode 108b as shown in the figure). Currently, the requirement for the durability of a solar module is rather high (about 20 years). If the situation of an interconnecting wire falling off occurs after a solar module is mounted on a roof, the troubleshooting and repair will be very time and labor-consuming.

### SUMMARY

Therefore, an object of the present invention is to provide an improved photovoltaic module and its junction box.

According to the aforementioned object, a junction box of a photovoltaic module is provided, and includes a box body, an electrode and a metal fastener. The electrode is located in the box body for electrically connecting to an interconnecting wire of a photovoltaic panel. The metal fastener is fixed on the electrode for clamping the interconnecting wire between the metal fastener and the electrode.

According to an embodiment of the present invention, the metal fastener is an L-shaped plate.

According to another embodiment of the present invention, the metal fastener is locked on the electrode through a screw.

According to another embodiment of the present invention, a solder material is used for welding the electrode and the interconnecting wire.

According to another embodiment of the present invention, the box body further includes a cover plate.

According to the aforementioned object, a photovoltaic module is provided, and includes a photovoltaic panel, a box body, an electrode and a metal fastener. The photovoltaic panel has a plurality of interconnecting wires. The electrode is located in the box body for electrically connecting to an interconnecting wire of a photovoltaic panel. The metal fastener is fixed on the electrode for clamping an interconnecting wire between the metal fastener and the electrode.

According to an embodiment of the present invention, the metal fastener is an L-shaped plate.

According to another embodiment of the present invention, the metal fastener is locked on the electrode through a screw.

According to another embodiment of the present invention, a solder material is used for welding the electrode and the interconnecting wires.

According to another embodiment of the present invention, the box body further includes a cover plate.

As described above, in the application of the photovoltaic module and the junction box thereof of the present invention, the metal fastener is used to fix the interconnecting wires of the photovoltaic module, which not only facilitates the firm welding of the interconnecting wires but also provides the double fixing of the interconnecting wires, thereby ensuring the stability of the connection of the two interconnecting wires with the positive and negative electrodes of the junction box.

### BRIEF DESCRIPTION OF THE DRAWINGS

The above and other objectives, features, advantages and embodiments of the present invention can be more fully understood with reference to the accompanying drawings as follows:

FIG. 1 is a cross-sectional view of a conventional photovoltaic module;

FIG. 2 is a cross-sectional view of a photovoltaic module according to an embodiment of the present invention;

FIG. 3 is a top view of the photovoltaic module shown in FIG. 2; and

FIG. 4 is a cross-sectional view viewed along a sectional line 4-4′ shown in FIG. 3.

### DETAILED DESCRIPTION

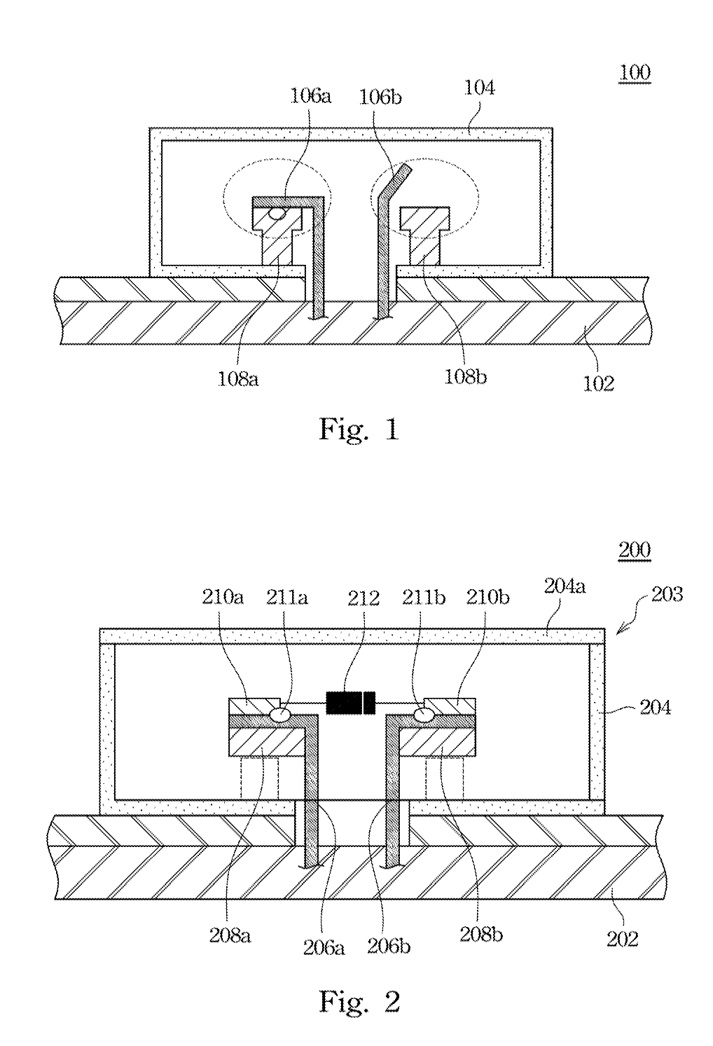

FIG. 2 is a cross-sectional view of a photovoltaic module 200 according to an embodiment of the present invention. When a box body 204 of a junction box 203 is mounted on the back side of a photovoltaic panel 202, interconnecting wires 206a and 206b of the photovoltaic panel 202 pass through an opening of the box body 204, and are respectively electrically connected to two electrodes 208a and 208b. Unlike the connection manner of FIG. 1, in this embodiment, metal fasteners 210a and 210b are added, which are respectively pressed and connected onto the interconnecting wires 206a and 206b, thereby respectively clamping the interconnecting wires 206a and 206b between the electrodes 208a and 208b and the metal fasteners 210a and 210b. Therefore, the interconnecting wires 206a and 206b will not easily drop off in the above clamping state. In another embodiment, the two interconnecting wires 206a and 206b are respectively connected and fixed to the two electrodes 208a and 208b in a welding manner (for example, using solder materials 211a and 211b shown in the figure for welding), thereby further reducing the connection impedance. Compared with a conventional electrical connection manner (for example, the aforementioned manner shown in FIG. 1), in this embodiment, when welding is being performed, the interconnecting wires 206a and 206b have been first fixed between the electrodes 208a and 208b and the metal fasteners 210a and 210b for facilitating the improvement of firm welding in the subsequent steps.

In another embodiment, a fixing member such as a screw or a rivet may be used to replace the solder materials. In other words, after the metal fasteners 210a and 210b are used to clamp the interconnecting wires 206a and 206b, the fixing member such as a screw or a rivet may be used to electrically connect the interconnecting wires 206a and 206b to the electrodes 208a and 208b, and thus the solder materials are no longer needed for welding.

On the other hand, this embodiment provides a double manner of “metal fastener” and “welding” to fix the interconnecting wires 206a and 206b on the electrodes 208a and 208b. Even if the welding spots cannot provide a fixing function, the metal fasteners 210a and 210b may still exert the fixing function. Therefore, the aforementioned “double fixing manner of the metal fasteners and welding” ensures the stability of the connection of the interconnecting wires 206a and 206b with the electrodes 208a and 208b.

Furthermore, the box body 204 has a cover plate 204a for an implementing or assembling worker to open or detach the cover plate 204a, so as to carry out the assembling and welding work of the metal fasteners.

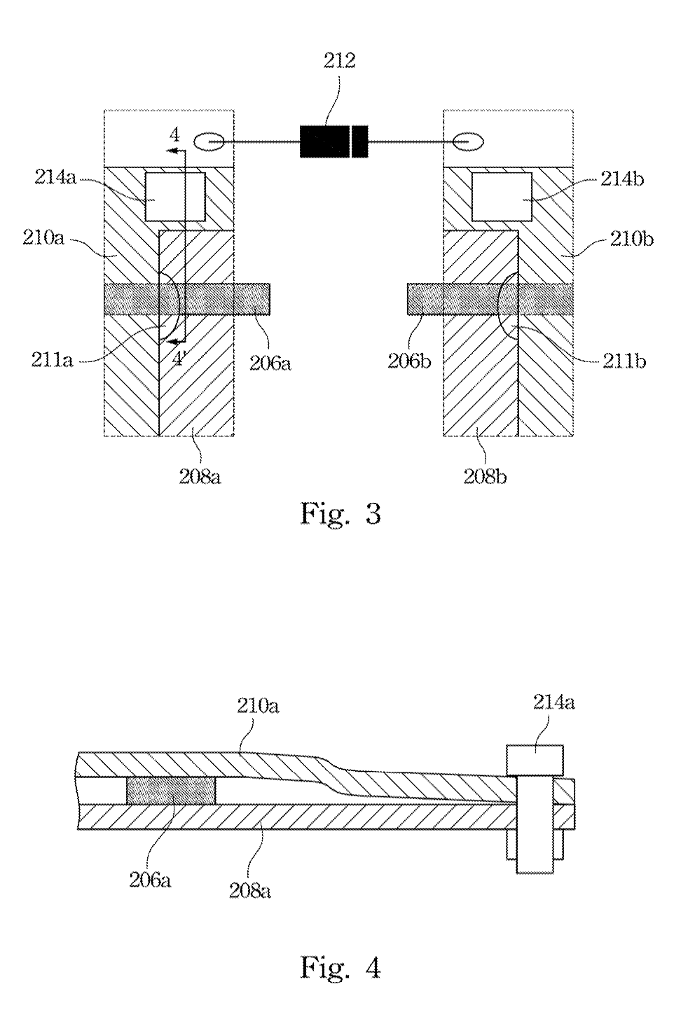

FIG. 3 is a top view of the photovoltaic module in FIG. 2. In this embodiment, each of the metal fasteners 210a and 210b is an L-shaped metal plate with one side fixed on the electrode 208a or 208b and the other side pressed on the interconnecting wire 206a or 206b. In this embodiment, the metal fasteners may be plates which are in another shape (for example, an elongated shape), and the present invention is not limited to the aforementioned L-shaped metal plates. Furthermore, a diode 212 is usually installed between the two electrodes 208a and 208b) for improving the electrical. performance.

FIG. 4 is a cross-sectional view viewed along a sectional line 4-4′ shown in FIG. 3. As shown in the figure, one end of the metal fastener 210a is fixed on the electrode 208a through a screw 214a, and the other end thereof is pressed on the interconnecting wire 206a. Therefore, the interconnecting wire 206a is clamped between the metal fastener 210a and the electrode 208a, and meanwhile power can be transmitted through the metal fastener 210a and the electrode 208a. Furthermore, the present invention is not limited to the metal fasteners fixed on the electrodes through screws (for example, screws 214a and 214b), and the metal fasteners also may be fixed in another manner (for example, rivets).

From the aforementioned embodiments of the present invention, in the application of the photovoltaic module and the junction box thereof of the present invention, the metal fasteners are used to fix the interconnecting wires of the photovoltaic module, thereby not only facilitating the firm welding of the. interconnecting wires but also providing the double fixing of the interconnecting wires, thus ensuring the connection stability of the interconnecting wires with the electrodes.

Although the present invention has been described in considerable detail with reference to certain embodiments thereof, other embodiments are possible. Various alternations and modifications can be made to these certain embodiments by those skilled in the art without departing from the spirit and scope of the present invention. Such alternations and modifications are intended to fall within the scope of the appended claims.

What is claimed is:

1. A junction box of a photovoltaic module comprising:
a box body;
an electrode located in the box body for electrically connecting an interconnecting wire of a photovoltaic panel; and
a metal fastener fixed on the electrode for clamping the interconnecting wire between the metal fastener and the electrode.

2. The junction box of a photovoltaic module of claim 1, wherein the metal to fastener is an L-shaped plate.

3. The junction box of a photovoltaic module of claim 1, further comprising:
a screw for locking the metal fastener on the electrode.

4. The junction box of a photovoltaic module of claim 1, further comprising:
a solder material for welding the electrode and the interconnecting wire.

5. The junction box of a photovoltaic module of claim 1, wherein the box body further comprises a cover plate.

6. A photovoltaic module comprising:
a photovoltaic panel having a plurality of interconnecting wires;
a box body;
an electrode located in the box body for electrically connecting an interconnecting wire of a photovoltaic panel; and
a metal fastener fixed on the electrode for clamping at least one of the interconnecting wires between the metal fastener and the electrode.

7. The photovoltaic module of claim 6, wherein the metal fastener is an L-shaped plate.

8. The photovoltaic module of claim 6, further comprising:
a screw for locking the metal fastener on the electrode.

9. The photovoltaic module of claim 6, further comprising:
a solder material for welding the electrode and the interconnecting wire.

10. The photovoltaic module of claim 6, wherein the box body further comprises a cover plate.
